(19) United States
(12) Patent Application Publication
(10) Pub. No.: US 2012/0097948 A1
(43) Pub. Date: Apr. 26, 2012

(54) THIN FILM TRANSISTOR

(76) Inventors: Jeong-Hwan Kim, Yongin-city (KR); Ki-Hong Kim, Yongin-city (KR); Yong-Jae Jang, Yongin-city (KR); Jung-Hyun Kim, Yongin-city (KR)

(21) Appl. No.: 13/193,463

(22) Filed: Jul. 28, 2011

(30) Foreign Application Priority Data
Oct. 22, 2010 (KR) 10-2010-0103545

(51) Int. Cl. H01L 29/786

(52) U.S. Cl. 257/57; 257/66; 257/E29.273

(57) ABSTRACT

A thin film transistor includes a substrate, a gate electrode on the substrate, a gate insulating layer covering the gate electrode, a first semiconductor layer and a second semiconductor layer overlapping the gate electrode on the gate insulating layer and separated from each other, a first source electrode and a first drain electrode on the first semiconductor layer and on opposite sides of the gate electrode, and a second source electrode and a second drain electrode on the second semiconductor layer and on opposite sides of the gate electrode, wherein the first source electrode is coupled to the second source electrode through a source connection overlapping the gate electrode, and the first drain electrode is coupled to the second drain electrode, such that the on current and off current characteristics of the thin film transistor may be constantly maintained regardless of alignment error.

### CROSS-REFERENCE TO RELATED APPLICATION

This application claims priority to and the benefit of Korean Patent Application No. 10-2010-0103545 filed in the Korean Intellectual Property Office on Oct. 22, 2010, the entire contents of which are incorporated herein by reference.

### BACKGROUND

1. Field

Embodiments of the present invention relate to a thin film transistor.

2. Description of Related Art

Generally, thin film transistors include a gate electrode, a semiconductor layer formed on the gate electrode and electrically insulated from the gate electrode by a gate insulating layer, and a source electrode and a drain electrode contacting the semiconductor layer.

When the gate insulating layer of the thin film transistor is contaminated by a metal or a dopant, the contaminant allows for a leakage current, or an off current (Ioff) (e.g., a current flowing through the thin film transistor despite the thin film transistor being turned off), to be generated during operation of the transistor. Although the thin film transistor is designed such that electrons do not move into the semiconductor layer when the thin film transistor is in the off state, and therefore no current flows in practice, the leakage current does exist, since electrons do pass through semiconductor layer while the thin film transistor is in the off state. To prevent or reduce the leakage current and a variation of a threshold voltage (Vth), an offset region where the gate electrode does not overlap with the source electrode and drain electrode is formed in the semiconductor layer.

In the thin film transistor including the offset region, even if an alignment error or an overlay shift between the gate electrode and the source and drain electrodes is generated within an alignment margin range, the characteristic of an on current (Ion) or an off current (Ioff) is changed corresponding to a change in size of the source offset region or the drain offset region. That is, when the size of the source offset region between the source electrode and the gate electrode is increased by the alignment error, the on current is increased, and when the size of the drain offset region between the drain electrode and the gate electrode is increased by the alignment error, the size of the on current is the same as the size of the on current when the alignment error is not generated.

The above information disclosed in this Background section is only for enhancement of understanding of the background of the described technology, and therefore may contain information that does not form the prior art that is already known in this country to a person of ordinary skill in the art.

### SUMMARY

Embodiments of the present invention provide a thin film transistor having small change in operating characteristics even when the size of an offset region is changed due to an alignment error.

A thin film transistor according to an exemplary embodiment of the present invention includes a substrate, a gate electrode on the substrate, a gate insulating layer covering the gate electrode, a first semiconductor layer and a second semiconductor layer overlapping the gate electrode on the gate insulating layer and separated from each other, a first source electrode and a first drain electrode on the first semiconductor layer and on opposite sides of the gate electrode, and a second source electrode and a second drain electrode on the second semiconductor layer and on opposite sides of the gate electrode, wherein the first source electrode is coupled to the second source electrode through a source connection overlapping the gate electrode, and the first drain electrode is coupled to the second drain electrode.

The first semiconductor layer may include a first source region electrically contacting the first source electrode, a first drain region electrically contacting the first drain electrode, and a first channel region between the first source region and the first drain region, wherein a first source offset region is between the first source region and the first channel region, and a first drain offset region is between the first drain region and the first channel region.

A width of the first source offset region may be a distance between the gate electrode and the first source electrode, and a width of the first drain offset region may be a distance between the gate electrode and the first drain electrode.

The second semiconductor layer may include a second source region electrically contacting the second source electrode, a second drain region electrically contacting the second drain electrode, and a second channel region between the second source region and the second drain region, wherein a second source offset region is between the second source region and the second channel region, and a second drain offset region is between the second drain region and the second channel region.

A width of the second source offset region may be a distance between the gate electrode and the second source electrode, and a width of the second drain offset region may be a distance between the gate electrode and the second drain electrode.

The first source offset region and the second source offset region may be on opposite sides of the gate electrode, and the first drain offset region and the second drain offset region may be on opposite sides of the gate electrode.

The first source electrode and the second source electrode may be on opposite sides of the gate electrode, and the first drain electrode and the second drain electrode may be on opposite sides of the gate electrode.

The source connection may be at a same layer as the first source electrode and the second source electrode.

The source connection may be insulated from the gate electrode and may cross the gate electrode.

The first drain electrode and the second drain electrode may be at a same layer as, and may be coupled through, a drain connection.

The drain connection might not overlap the gate electrode.

The first semiconductor layer and the second semiconductor layer may include a material selected from the group consisting of amorphous silicon, polysilicon, an oxide semiconductor, microcrystalline silicon, and laser crystallized silicon.

A width of the first source offset region is a distance between the gate electrode and the first source electrode and is in a range of about 1 μm to about 10 μm, and a width of the first drain offset region is a distance between the gate electrode and the first drain electrode and is in a range of about 1 μm to about 10 μm, and a width of the second source offset region may be a distance between the gate electrode and the second source electrode and may be in a range of about 1 μm to about 10 μm, and a width of the second drain offset region may be a distance between the gate electrode and the second drain electrode and may be in a range of about 1 μm to about 10 μm.

A thin film transistor according to another exemplary embodiment of the present invention includes a plurality of thin film transistors, each of the thin film transistors including a substrate, a gate electrode on the substrate, a gate insulating layer covering the gate electrode, a first semiconductor layer and a second semiconductor layer overlapping the gate electrode on the gate insulating layer and separated from each other, a first source electrode and a first drain electrode on the first semiconductor layer and on opposite sides of the gate electrode, and a second source electrode and a second drain electrode on the second semiconductor layer and on opposite sides of the gate electrode, wherein the first source electrode of each thin film transistor is coupled to the second source electrode through a source connection overlapping the gate electrode, and the first drain electrode is coupled to the second drain electrode.

The first source electrode and the second source electrode may be on opposite sides of the gate electrode, and the first drain electrode and the second drain electrode may be on opposite sides of the gate electrode.

The gate electrodes of the plurality of thin film transistors may be coupled to each other.

The first source electrodes and the second source electrodes of the plurality of thin film transistors may be coupled to each other.

The first drain electrodes and the second drain electrodes of the plurality of thin film transistors may be coupled to each other.

A thin film transistor according to yet another exemplary embodiment of the present invention includes a substrate a first semiconductor layer and a second semiconductor layer on the substrate and separated from each other, a semiconductor insulating layer covering the first semiconductor layer and the second semiconductor layer, a gate electrode overlapping the first semiconductor layer and the second semiconductor layer on the semiconductor insulating layer, a gate insulating layer covering the gate electrode and the semiconductor insulating layer, a first source electrode and a first drain electrode on the gate insulating layer and on opposite sides of the gate electrode, and a second source electrode and a second drain electrode on the gate insulating layer and on opposite sides of the gate electrode, wherein the first source electrode is coupled to the second source electrode through a source connection overlapping the gate electrode, and the first drain electrode is coupled to the second drain electrode through a drain connection.

The first source electrode and the second source electrode may be on opposite sides of the gate electrode, and the first drain electrode and the second drain electrode may be on opposite sides of the gate electrode.

According to embodiments of the present invention, the first source offset region and the second source offset region are opposite to each other with respect to (e.g., with reference to, relative to) the gate electrode, and the first drain offset region and the second drain offset region are opposite to each other with respect to the gate electrode (e.g., are on opposite sides of the gate electrode), such that the on current and off current characteristics (e.g., the electrical properties) of the thin film transistor may be constantly maintained despite the presence of the alignment error between the gate electrode and the first and second source and drain electrodes.

Also, a plurality of thin film transistors have the first source offset region and the second source offset region opposite each other with respect to the gate electrode, and have the first drain offset region and the second drain offset region opposite each other with respect to the gate electrode, and the source electrodes and the drain electrodes of the unit thin film transistors are respectively coupled to each other to amplify the on current such that decrease of the on current due to the plurality of source offset regions and drain offset regions may be prevented or reduced.

### BRIEF DESCRIPTION OF THE DRAWINGS

FIG. 1 is a layout view of a thin film transistor according to a first exemplary embodiment of the present invention.

FIG. 2 is a cross-sectional view of the thin film transistor of the embodiment shown in FIG. 1 taken along the lines II-II′ and II′-II″.

FIG. 3 is an equivalent circuit of the thin film transistor of the embodiment shown in FIG. 1.

FIG. 4 is a layout view of a thin film transistor when a right side alignment error is generated in the thin film transistor of the embodiment shown in FIG. 1.

FIG. 5 is a cross-sectional view of the thin film transistor of the embodiment shown in FIG. 4 taken along the lines V-V and V′-V″.

FIG. 6 is a layout view of a thin film transistor when a left side alignment error is generated in the thin film transistor of the embodiment shown in FIG. 1.

FIG. 7 is a cross-sectional view of the thin film transistor of FIG. 6 taken along the lines VII-VII′ and VII′-VII″.

FIG. 8 is a graph showing electric characteristics of the thin film transistor of the embodiment shown in FIG. 1.

FIG. 9 is a layout view of a thin film transistor according to a second exemplary embodiment of the present invention.

FIG. 10 is a cross-sectional view of the thin film transistor of the embodiment shown in FIG. 9 taken along the lines X-X′ and X′-X″.

FIG. 11 is a layout view of a thin film transistor according to a third exemplary embodiment of the present invention.

### DETAILED DESCRIPTION

Hereinafter, several embodiments of the present invention are shown and described in detail with reference to the accompanying drawings to enable performance of the embodiments of the present invention by those skilled in the art. The embodiments of the present invention may be modified in various different ways, and the present invention is not limited to embodiments described herein.

Further, in the described embodiments, like reference numerals designate like elements throughout the specification representatively with respect to a first embodiment, and only elements of additional embodiments that are different than the elements of the first embodiment will be described. Descriptions of some of the parts not relating to the present invention are omitted.

Further, since sizes and thicknesses of elements, components, and constituent members shown in the accompanying drawings may be arbitrary and are primarily given for a better understanding and for ease of description, the elements, components, and constituent members are not necessarily shown to scale, and the present invention is not limited to the illustrated sizes and thicknesses. Also, the thicknesses of some layers and areas may be exaggerated. Furthermore, it should be understood that when an element such as a layer, film, region, or substrate is referred to as being “on” another element, it can be directly on the other element or one or more intervening elements may also be present.

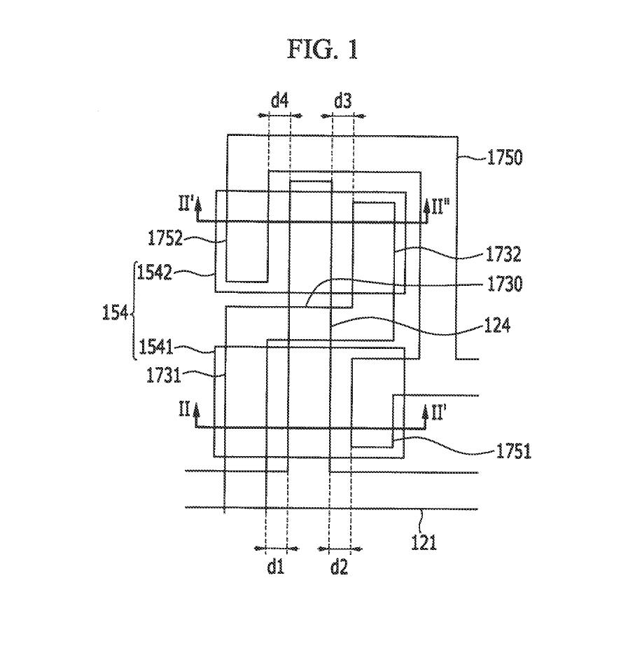

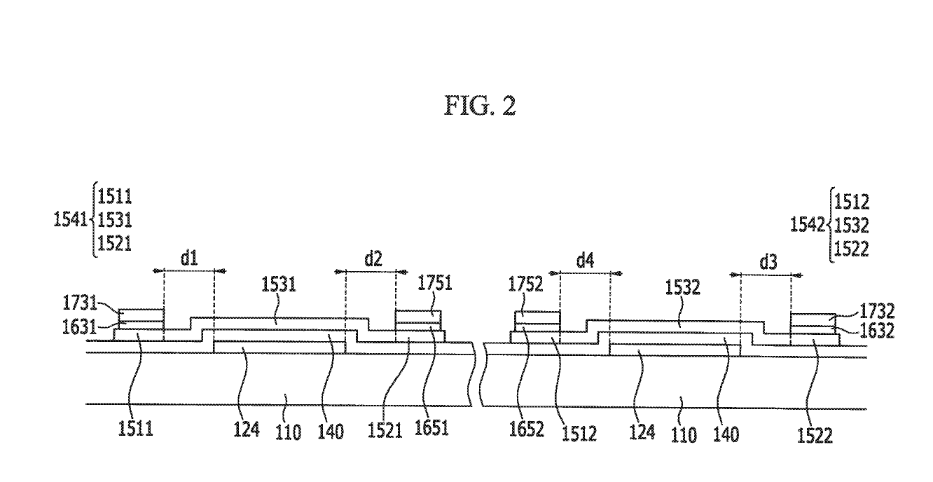

Referring to FIGS. 1 and 2, a thin film transistor according to a first exemplary embodiment of the present invention will be described.

FIG. 1 is a layout view of a thin film transistor according to the first exemplary embodiment, and FIG. 2 is a cross-sectional view of the thin film transistor of the embodiment shown in FIG. 1 taken along the lines II-II′ and II′-II″.

As shown in FIG. 1 and FIG. 2, in a thin film transistor according to the first exemplary embodiment, a gate electrode 124 is formed on a substrate 110 made of transparent glass or plastic. The gate electrode 124 extends in a substantially transverse direction is coupled to a gate line 121, and is for transmitting a gate signal.

A gate insulating layer 140 made of silicon nitride (SiNₓ) or silicon oxide (SiOₓ) is formed on the gate electrode 124. The gate insulating layer 140 covers and insulates the gate electrode 124.

A semiconductor layer 154 is formed on the gate insulating layer 140, and the semiconductor layer 154 includes a first semiconductor layer 1541 and a second semiconductor layer 1542 separated from the first semiconductor layer 1541. The first semiconductor layer 1541 and the second semiconductor layer 1542 both overlap one gate electrode 124 (e.g., both overlap a different respective region of the gate electrode 124).

The first semiconductor layer 1541 and the second semiconductor layer 1542 may include a material selected from the group consisting of amorphous silicon (a-Si), polysilicon (poly-Si), an oxide semiconductor, microcrystal silicon, and laser crystallized silicon.

The first semiconductor layer 1541 and the second semiconductor layer 1542 each include a respective source region (1511, 1522), a respective drain region (1521, 1512), and a respective channel region (1531, 1532), each of the channel regions (1531, 1532) being positioned between the respective source region (1511, 1522) and the respective drain region (1521, 1512).

The first source offset region d1 is formed between the source region 1511 and the channel region 1531 of the first semiconductor layer 1541, and the first drain offset region d2 is formed between the drain region 1521 and the channel region 1531 of the first semiconductor layer 1541. The second source offset region d3 is formed between the source region 1522 and the channel region 1532 of the second semiconductor layer 1542, and the second drain offset region d4 is formed between the drain region 1512 and the channel region 1532 of the second semiconductor layer 1542.

The first source offset region d1 and the second source offset region d3 are opposite to each other with reference to the gate electrode 124, and the first drain offset region d2 and the second drain offset region d4 are opposite to each other with reference to the gate electrode 124. For example, and referring to FIG. 1, d1 and d4 are on a left side of the gate electrode 124, and d2 and d3 are on a right side of the gate electrode 124). When the thin film transistor is in the off state, the first and second source offset regions d1 and d3 and the first and second drain offset regions d2 and d4 block a path of electron movement of the first semiconductor layer 1541 and the second semiconductor layer 1542 such that the generation of a leakage current is reduced or prevented.

The width of the first and second source offset regions d1 and d3 may be in the range of 1 μm to 10 μm, and the width of the first and second drain offset regions d2 and d4 may be in the range of 1 μm to 10 μm. When the width of the first and second source offset regions d1 and d3 and the width of the first and second drain offset regions d2 and d4 are less than 1 μm, the leakage current may be easily generated, and when the width of the first and second source offset regions d1 and d3 and the width of the first and second drain offsets region d2 and d4 are larger than 10 μm, an on current (Ion) (e.g., current through the transistor when turned on) may be decreased.

First ohmic contact members 1631 and 1651 are formed on the first semiconductor layer 1541, and second ohmic contact members 1632 and 1652 are formed on the second semiconductor layer 1542. The first ohmic contact members 1631 and 1651 and the second ohmic contact members 1632 and 1652 may be made of n+ hydrogenated amorphous silicon in which n-type impurities, such as phosphorus, are doped at a high concentration, or may also be made of silicide. The first ohmic contact members 1631 and 1651 are formed in a pair on the first semiconductor layer 1541, and the second ohmic contact members 1632 and 1652 are formed in a pair on the second semiconductor layer 1542.

A first source electrode 1731 and a first drain electrode 1751 are respectively formed on the first ohmic contact members 1631 and 1651, and a second source electrode 1732 and a second drain electrode 1752 are respectively formed on the second ohmic contact members 1632 and 1652. The first and second ohmic contact members 1631, 1651, 1632, and 1652 are between the underlying first and second semiconductor layers 1541 and 1542, and the overlying first and second source and drain electrodes 1731, 1732, 1751, and 1752, thereby decreasing the resistance therebetween. For example, the first ohmic contact member 1631 is formed between the first semiconductor layer 1541 and the first source electrode 1731; the first ohmic contact member 1651 is formed between the first semiconductor layer 1541 and the first drain electrode 1751; the second ohmic contact member 1652 is formed between the second semiconductor layer 1542 and the second drain electrode 1752; and the second ohmic contact member 1632 is formed between the second semiconductor layer 1542 and the second source electrode 1732.

The first drain electrode 1751 faces the first source electrode 1731 with respect to the gate electrode 124 (e.g., with the gate electrode 124 therebetween). The first source electrode 1731 and the gate electrode 124 do not overlap each other, and are separated from each other by an interval (e.g., a predetermined interval) such that the first source offset region d1 is in the first semiconductor layer 1541 between the first source electrode 1731 and the gate electrode 124 (e.g., the first source offset region d1 is a region whose width is a horizontal distance between points or positions aligned with proximate, or facing, vertical edges of the first source electrode 1731 and the gate electrode 124). Also, the first drain electrode 1751 and the gate electrode 124 do not overlap each other, and are separated from each other by an interval (e.g., a predetermined interval) such that the first drain offset region d2 is formed in the first semiconductor layer 1541 between the first drain electrode 1751 and the gate electrode 124 (e.g., the first drain offset region d2 is a region whose width is a horizontal distance between positions aligned with proximate, or facing, vertical edges of the first drain electrode 1751 and the gate electrode 124).

The second drain electrode 1752 faces the second source electrode 1732 with respect to the gate electrode 124. The second source electrode 1732 and the gate electrode 124 do not overlap each other, and are separated from each other by an interval (e.g., a predetermined interval) such that the second source offset region d3 is formed in the second semiconductor layer 1542 between the second source electrode 1732 and the gate electrode 124 (e.g., the second source offset region d3 is a region whose width is a horizontal distance between points or positions aligned with proximate, or facing, vertical edges of the second source electrode 1732 and the gate electrode 124). Also, the second drain electrode 1752 and the gate electrode 124 do not overlap each other, and are separated from each other by an interval (e.g., a predetermined interval) such that the second drain offset region d4 is formed in the second semiconductor layer 1542 between the second drain electrode 1752 and the gate electrode 124 (e.g., the second drain offset region d4 is a region whose width is a horizontal distance between points or positions aligned with proximate, or facing, vertical edges of the second drain electrode 1752 and the gate electrode 124).

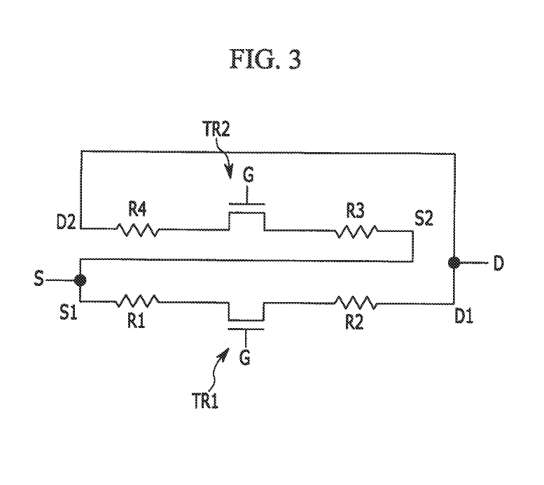

The gate electrode 124, the first semiconductor layer 1541, the first source electrode 1731, and the first drain electrode 1751 form the first thin film transistor (TR1, shown in FIG. 3), and the gate electrode 124, the second semiconductor layer 1542, the second source electrode 1732, and the second drain electrode 1752 form the second thin film transistor (TR2, shown in FIG. 3).

The first source electrode 1731 and the second source electrode 1732 are located at opposite positions with respect to the gate electrode 124, and the first drain electrode 1751 and the second drain electrode 1752 are located at opposite positions with respect to the gate electrode 124. For example, and referring to FIG. 1, the first source electrode 1731 and the second drain electrode 1752 are on the left side of the gate electrode 124, while the second source electrode 1732 and the first drain electrode 1751 are on the right side of the gate electrode 124.

The first source electrode 1731 is coupled to the second source electrode 1732 through a source connection 1730 overlapping the gate electrode 124, and the first drain electrode 1751 is coupled to the second drain electrode 1752 through a drain connection 1750, which does not overlap the gate electrode 124.

The source connection 1730 is positioned at the same layer as the first source electrode 1731 and the second source electrode 1732, and the source connection 1730 is insulated from and crosses the gate electrode 124. Also, the drain connection 1750 is positioned at the same layer as the first drain electrode 1751 and the second drain electrode 1752, and the first drain electrode 1751 and the second drain electrode 1752 are coupled through the drain connection 1750.

The width of the first source offset region d1 is the same as the distance between the gate electrode 124 and the first source electrode 1731 (e.g., the horizontal distance between a point corresponding to a vertical edge of the gate electrode 124 facing the first source electrode 1731 and a point corresponding to a vertical edge of the first source electrode 1731 facing the gate electrode 124), and the width of the first drain offset region d2 is the same as the distance between the gate electrode 124 and the first drain electrode 1751 (e.g., the horizontal distance between a point corresponding to a vertical edge of the gate electrode 124 facing the first drain electrode 1751 and a point corresponding to a vertical edge of the first drain electrode 1751 facing the gate electrode 124). Also, the width of the second source offset region d3 is the same as the distance between the gate electrode 124 and the second source electrode 1732 (e.g., the horizontal distance between a point corresponding to a vertical edge of the gate electrode 124 facing the second source electrode 1732 and a point corresponding to a vertical edge of the second source electrode 1732 facing the gate electrode 124), and the width of the second drain offset region d4 is the same as the distance between the gate electrode 124 and the second drain electrode 1752 (e.g., the horizontal distance between a point corresponding to a vertical edge of the gate electrode 124 facing the second drain electrode 1752 and a point corresponding to a vertical edge of the second drain electrode 1752 facing the gate electrode 124).

As described above, the first source offset region d1 and the second source offset region d3 face each other with respect to the gate electrode 124, the first drain offset region d2 and the second drain offset region d4 face each other with respect to the gate electrode 124, and the first source electrode 1731 is coupled to the second source electrode 1732 through the source connection 1730 overlapping the gate electrode 124 such that symmetry of the source offset regions d1 and d3 and the drain offset regions d2 and d4 (e.g., symmetry with respect to the gate electrode 124) is maintained (e.g., d1/d3=d4/d2=d1/d2=d4/d3) even though an alignment error is generated between the gate electrode 124 and the first and second source and drain electrodes 1531, 1532, 1751, and 1752, and the characteristics of the on current and the off current of the thin film transistor may be constantly maintained.

Also, in the thin film transistor according to the first exemplary embodiment, even though the application direction of a bias voltage is changed from being from the source electrode to the drain electrode to being from the drain electrode to the source electrode, symmetry of the source offset regions and the drain offset regions may be maintained.

Also, if the alignment error is generated within an alignment margin range, by using the thin film transistor according to the first exemplary embodiment as a thin film transistor that is positioned at a region having a wide characteristic distribution, such as a thin film transistor for a gate driving circuit, a thin film transistor for a circuit for electrostatic protection, or a thin film transistor for a visual test, on current and off current characteristics of the thin film transistor may be constantly maintained.

In reference to the thin film transistor according to the first exemplary embodiment, the operation in which the on current and off current characteristics of the thin film transistor are constantly maintained in spite of the alignment error between the first and second source electrodes 1731 and 1732 and the first and second drain electrodes 1751 and 1752 will be described with reference to FIGS. 3 to 7.

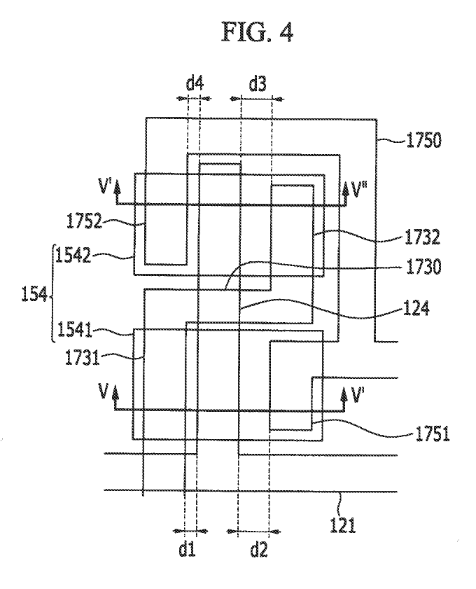

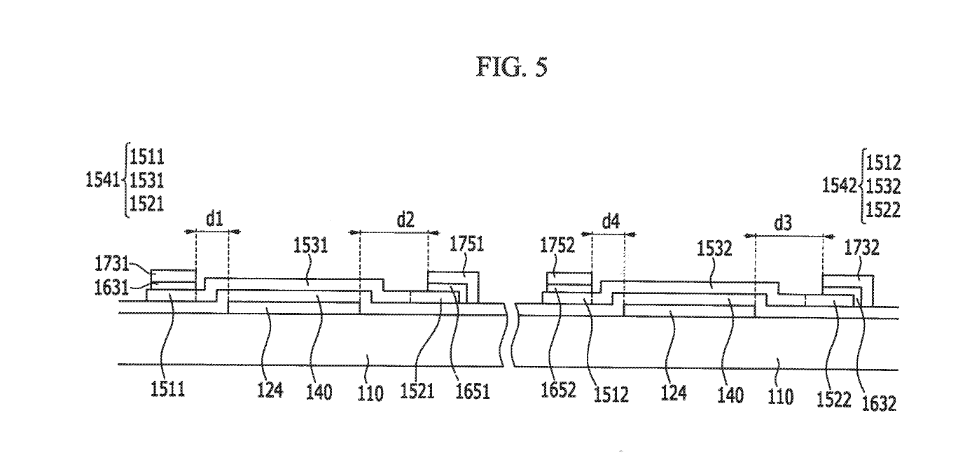

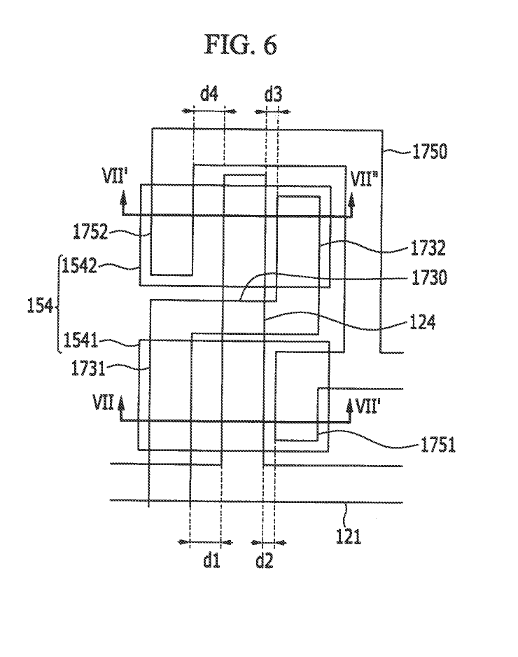

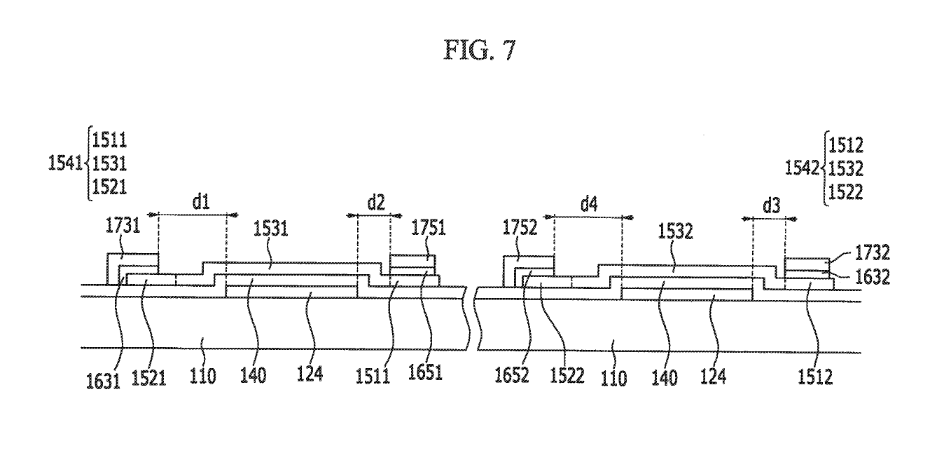

FIG. 3 is an equivalent circuit of the thin film transistor of the embodiment shown in FIG. 1; FIG. 4 is a layout view of a thin film transistor when a right side alignment error is generated in the thin film transistor of the embodiment shown in FIG. 1; FIG. 5 is a cross-sectional view of the thin film transistor of the embodiment shown in FIG. 4 taken along the lines V-V′ and V′-V″; FIG. 6 is a layout view of a thin film transistor when a left side alignment error is generated in the thin film transistor of the embodiment shown in FIG. 1; and FIG. 7 is a cross-sectional view of the thin film transistor of the embodiment shown in FIG. 6 taken along the lines VII-VII′ and VII′-VII″.

Firstly, as shown in FIG. 3, in the thin film transistor according to the first exemplary embodiment, a first resistance R1 is formed by the first source offset region d1 between the first source electrode 1731 (S1) and the gate electrode 124 (G) of the first thin film transistor TR1, and a second resistance R2 is formed by the first drain offset region d2 between the first drain electrode 1751 (D1) and the gate electrode 124 (G) of the first thin film transistor TR1. Also, a third resistance R3 is formed by the second source offset region d3 between the second source electrode 1732 (S2) and the gate electrode 124 (G) of the second thin film transistor TR2, and a fourth resistance R4 is formed by the second drain offset region d4 between the second drain electrode 1752 (D2) and the gate electrode 124 (G) of the second thin film transistor TR2. Here, the first source electrode 1731 (S1) and the second source electrode 1732 (S2) are coupled to each other at the source connection 1730 (S), and the first drain electrode 1751 (D1) and the second drain electrode 1752 (D2) are coupled to each other at the drain connection 1750 (D). Even though the alignment error is generated between the gate electrode 124 and the first and second source and drain electrodes 1731, 1732, 1751, and 1752, the first resistance to the fourth resistance are all substantially equal to each other such that little to no error for the on current characteristic is generated.

Next, as shown in FIG. 4 and FIG. 5, when the first source electrode 1731 and the first drain electrode 1751 are moved rightwardly with respect to the gate electrode 124 such that the right side alignment error (e.g., d1<d2 and d4<d3) is generated, the second source electrode 1732 and the second drain electrode 1752 also move rightwardly. Here, although the right side alignment error is generated, the first resistance R1 and the fourth resistance R4 are about equal to each other, and the second resistance R2 and the third resistance R3 are about equal to each other. That is, the first resistance R1 and the fourth resistance R4 are about equally decreased, as d1 and d4 are about equally decreased by the right side alignment error, and the second resistance R2 and the third resistance R3 are about equally increased, as d2 and d3 are about equally increased by the right side alignment error. Accordingly, the sum of the first resistance R1 and the third resistance R3, which are coupled to each other, and the sum of the second resistance R2 and the fourth resistance R4, which are coupled to each other, become about equal to each other. That is, the sum of the first resistance R1 corresponding to the first source offset region d1 and the third resistance R3 corresponding to the second source offset region d3 is about equal to the sum of the second resistance R2 corresponding to the first drain offset region d2 and the fourth resistance R4 corresponding to the second drain offset region d4, as d1+d3 is about equal to d2+d4, and therefore little to no error for the on current or off current characteristics is generated.

Also, as shown in FIG. 6 and FIG. 7, when the first source electrode 1731 and the first drain electrode 1751 move leftwardly with respect to the gate electrode 124 such that the left side alignment error is generated (e.g., d1>d2 and d4>d3), the second source electrode 1732 and the second drain electrode 1752 also move leftwardly. Here, although the left side alignment error is generated, the first resistance R1 and the fourth resistance R4 are about equal to each other, and the second resistance R2 and the third resistance R3 are about equal to each other. That is, the first resistance R1 and the fourth resistance R4 are about equally increased, and the second resistance R2 and the third resistance R3 are about equally decreased. Accordingly, the sum of the first resistance R1 and the third resistance R3, which are coupled to each other, and the sum of the size of the second resistance R2 and the fourth resistance R4, which are coupled to each other, become about equal to each other. That is, the sum of the first resistance R1 corresponding to the first source offset region d1 and the third resistance R3 corresponding to the second source offset region d3 is about equal to the sum of the second resistance R2 corresponding to the first drain offset region d2 and the fourth resistance R4 corresponding to the second drain offset region d4, such that little to no error for the on current or off current characteristic is generated.

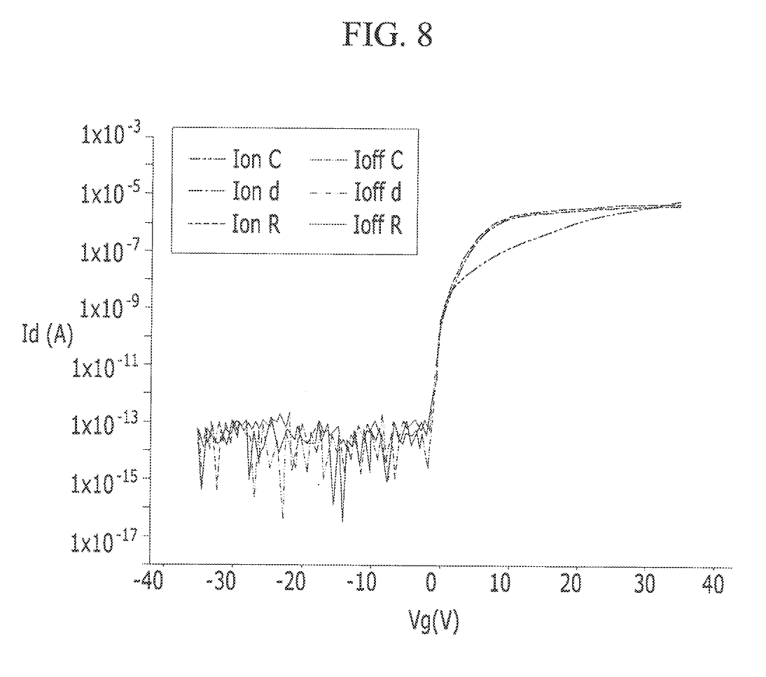

FIG. 8 is a graph measuring electric characteristics of the thin film transistor of the embodiment shown in FIG. 1. FIG. 8 shows a change of a drain current (Id) according to a gate voltage (Vg) of a thin film transistor (e.g., a graph of Id vs. Vg).

In detail, FIG. 8 shows an on current characteristic graph (Ion C) and an off current characteristic graph (Ioff C) when the alignment error is not generated, an on current characteristic graph (Ion R) and an off current characteristic graph (Ioff R) when a right side alignment error of 1.5 μm is generated, and an on current characteristic graph (Ion d) and an off current characteristic graph (Ioff d) when a left side alignment error of 1.5 μm is generated.

As shown in FIG. 8, the size of the on current is increased when the right side alignment error or the left side alignment error is generated, as compared with the case when no alignment error is generated. However, there is no substantial difference between the size of the on current corresponding to the right side alignment error and the size of the on current corresponding to the left side alignment error. Accordingly, it may be confirmed that the on current and off current characteristics of the thin film transistor are constantly maintained under the alignment error (e.g., regardless of the alignment error).

The first exemplary embodiment is a bottom gate structure in which the gate electrode 124 is positioned under the first and second semiconductor layers 1541 and 1542, however the present invention may be applied to a top gate structure in which the gate electrode 124 is positioned on or above the first and second semiconductor layers 1541 and 1542.

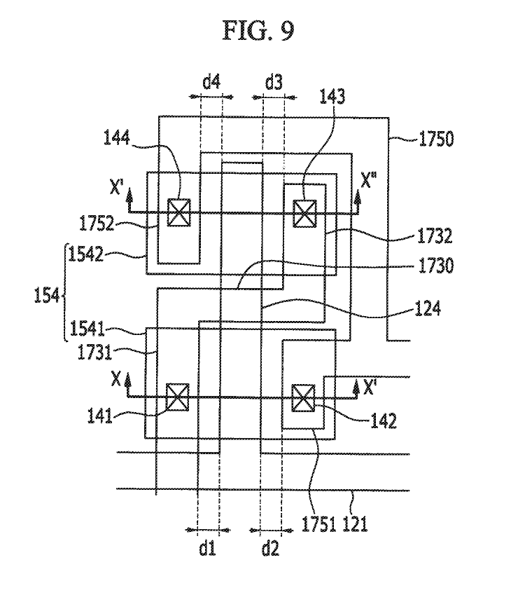

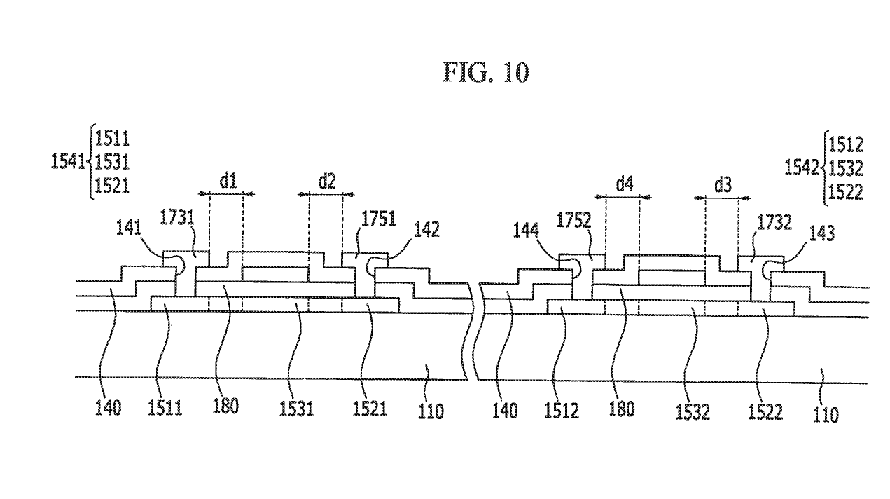

Next, a thin film transistor according to a second exemplary embodiment of the present invention will be described with reference to FIG. 9 and FIG. 10.

FIG. 9 is a layout view of a thin film transistor according to the second exemplary embodiment, and FIG. 10 is a cross-sectional view of the thin film transistor of FIG. 9 taken along the lines X-X′ and X′-X″.

The second exemplary embodiment, except for the top gate structure, is substantially equivalent to the first exemplary embodiment shown in FIG. 1 and FIG. 2, and overlapping description is omitted.

As shown in FIG. 9 and FIG. 10, in the thin film transistor according to the second exemplary embodiment, a semiconductor layer 154 is formed on a substrate 110, and the semiconductor layer 154 includes a first semiconductor layer 1541 and a second semiconductor layer 1542 separated from the first semiconductor layer 1541.

A semiconductor insulating layer 180 made of silicon nitride (SiNₓ) or silicon oxide (SiOₓ) is formed on the first semiconductor layer 1541 and the second semiconductor layer 1542. A gate electrode 124 overlapping the first semiconductor layer 1541 and the second semiconductor layer 1542 is formed on the semiconductor insulating layer 180. A gate insulating layer 140 made of silicon nitride (SiNₓ) or silicon oxide (SiOₓ) is formed on the gate electrode 124.

The gate insulating layer 140 and the semiconductor insulating layer 180 have a first source contact hole 141 and a first drain contact hole 142 exposing the first semiconductor layer 1541, and a second source contact hole 143 and a second drain contact hole 144 exposing the second semiconductor layer 1542.

The first source offset region d1 and the second source offset region d3 face each other with respect to the gate electrode 124 (e.g., are on opposite sides of the gate electrode 124), and the first drain offset region d2 and the second drain offset region d4 face each other with respect to the gate electrode 124 (e.g., are on opposite sides of the gate electrode 124).

A first source electrode 1731 coupled to the first semiconductor layer 1541 through the first source contact hole 141, and a first drain electrode 1751 coupled to the first semiconductor layer 1541 through the first drain contact hole 142, are formed on the gate insulating layer 140. Also, a second source electrode 1732 coupled to the second semiconductor layer 1542 through the second source contact hole 143, and a second drain electrode 1752 coupled to the second semiconductor layer 1542 through the second drain contact hole 144, are formed on the gate insulating layer 140.

The first source electrode 1731 and the second source electrode 1732 are opposite to each other with respect to the gate electrode 124 (e.g., are on opposite sides of the gate electrode 124), and the first drain electrode 1751 and the second drain electrode 1752 are opposite to each other with respect to the gate electrode 124 (e.g., are on opposite sides of the gate electrode 124). The first source electrode 1731 is coupled to the second source electrode 1732 through a source connection 1730 overlapping the gate electrode 124, and the first drain electrode 1751 is coupled to the second drain electrode 1752 through a drain connection 1750 that does not overlap the gate electrode 124.

As described above, the first source offset region d1 and the second source offset region d3 are opposite to each other with respect to the gate electrode 124 (e.g., are on opposite sides of the gate electrode 124), the first drain offset region d2 and the second drain offset region d4 are opposite to each other with respect to the gate electrode 124 (e.g., are on opposite sides of the gate electrode 124), and the first source electrode 1731 is coupled to the second source electrode 1732 through the source connection 1730 overlapping the gate electrode 124 such that the on current and off current characteristics of the thin film transistor may be constantly maintained regardless of the alignment error between the gate electrode 124 and the first and second source and drain electrodes 1731, 1732, 1751, and 1752.

In the first exemplary embodiment, a unit thin film transistor (e.g., a thin film transistor) in which the first and second semiconductor layers 1541 and 1542, the first and second source electrodes 1731 and 1732, and the first and second drain electrodes 1751 and 1752 are formed on one gate electrode 124 is described. However a plurality of unit thin film transistors may be formed and coupled to each other to amplify the on current such that decrease of the on current by a plurality of the first and second source offset regions d1 and d3 and a plurality of the first and second drain offset regions d2 and d4 may be reduced or prevented.

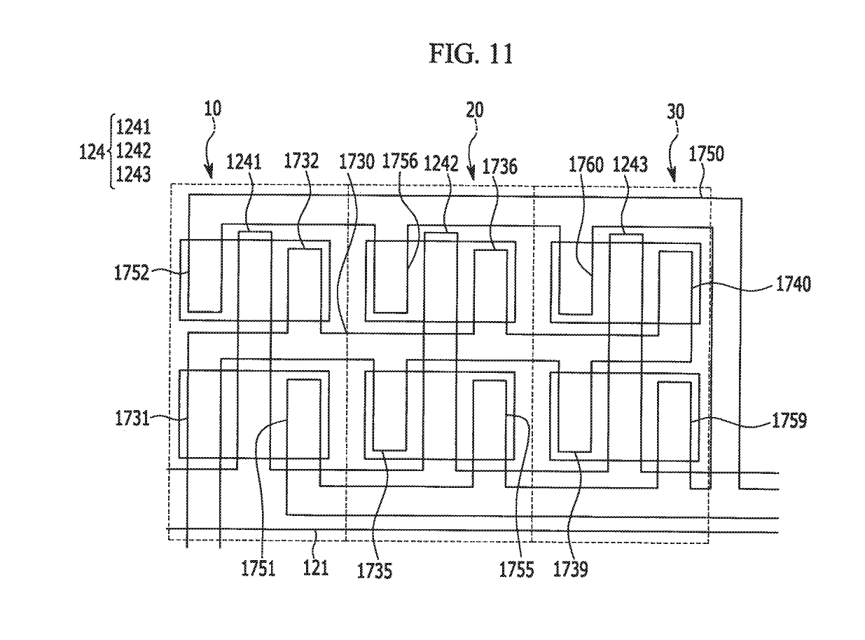

FIG. 11 is a layout view of a thin film transistor according to a third exemplary embodiment of the present invention.

The third exemplary embodiment, except for the presence of a plurality of unit thin film transistors, is substantially equivalent to the first exemplary embodiment shown in FIG. 1 and FIG. 2, and overlapping description is omitted.

As shown in FIG. 11, the thin film transistor according to the third exemplary embodiment includes a first unit thin film transistor 10, a second unit thin film transistor 20, and a third unit thin film transistor 30 that are coupled to each other. The third exemplary embodiment includes three unit thin film transistors 10, 20, and 30, however the number of unit thin film transistors is not limited to the present exemplary embodiment.

The first unit thin film transistor 10 includes first and second semiconductor layers 1541 and 1542, first and second source electrodes 1731 and 1732, and first and second drain electrodes 1751 and 1752 formed on a first gate electrode 1241. Also, the second unit thin film transistor 20 includes the first and second semiconductor layers 1541 and 1542, the first and second source electrodes 1735 and 1736, and the first and second drain electrodes 1755 and 1756 formed on a second gate electrode 1242. The third unit thin film transistor 30 includes the first and second semiconductor layers 1541 and 1542, the first and second source electrodes 1739 and 1740, and the first and second drain electrodes 1759 and 1760 formed on a third gate electrode 1243.

The first gate electrode 1241, the second gate electrode 1242, and the third gate electrode 1243 are coupled through a gate line 121. Also, the first and second source electrodes 1731 and 1732 of the first unit thin film transistor 10, first and second source electrodes 1735 and 1736 of the second unit thin film transistor 20, the first and second source electrodes 1739 and 1740 of the third unit thin film transistor 30 are coupled to each other. Also, the first and second drain electrodes 1751 and 1752 of the first unit thin film transistor 10, first and second drain electrodes 1755 and 1756 of the second unit thin film transistor 20, and first and second drain electrodes 1759 and 1760 of the third unit thin film transistor 30 are coupled to each other.

As described above, the on current is amplified through the plurality of unit thin film transistors such that a decrease in the on current by a plurality of the first and second source offset regions d1 and d3 and a plurality of the first and second drain offset regions d2 and d4 may be reduced or prevented.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims, and equivalents thereof.

### DESCRIPTION OF SOME OF THE REFERENCE CHARACTERS

| | |
|---|---|
| 124: | gate electrode |
| 140: | gate insulating layer |
| 1541: | first semiconductor layer |
| 1542: | second semiconductor layer |
| 1731: | first source electrode |
| 1732: | second source electrode |
| 1751: | first drain electrode |
| 1752: | second drain electrode |
| d1: | first source offset region |
| d2: | first drain offset region |
| d3: | second source offset region |
| d4: | second drain offset region |

What is claimed is:

1. A thin film transistor comprising:
a substrate;
a gate electrode on the substrate;
a gate insulating layer covering the gate electrode;
a first semiconductor layer and a second semiconductor layer overlapping the gate electrode on the gate insulating layer and separated from each other;
a first source electrode and a first drain electrode on the first semiconductor layer and on opposite sides of the gate electrode; and
a second source electrode and a second drain electrode on the second semiconductor layer and on opposite sides of the gate electrode,
wherein the first source electrode is coupled to the second source electrode through a source connection overlapping the gate electrode, and
the first drain electrode is coupled to the second drain electrode.

2. The thin film transistor of claim 1, wherein the first semiconductor layer comprises:
a first source region electrically contacting the first source electrode;
a first drain region electrically contacting the first drain electrode; and
a first channel region between the first source region and the first drain region,
wherein a first source offset region is between the first source region and the first channel region, and a first drain offset region is between the first drain region and the first channel region.

3. The thin film transistor of claim 2, wherein a width of the first source offset region is a distance between the gate electrode and the first source electrode, and a width of the first drain offset region is a distance between the gate electrode and the first drain electrode.

4. The thin film transistor of claim 2, wherein the second semiconductor layer comprises:
a second source region electrically contacting the second, source electrode;
a second drain region electrically contacting the second drain electrode; and
a second channel region between the second source region and the second drain region,
wherein a second source offset region is between the second source region and the second channel region, and a second drain offset region is between the second drain region and the second channel region.

5. The thin film transistor of claim 4, wherein a width of the second source offset region is a distance between the gate electrode and the second source electrode, and a width of the second drain offset region is a distance between the gate electrode and the second drain electrode.

6. The thin film transistor of claim 4, wherein the first source offset region and the second source offset region are on opposite sides of the gate electrode, and the first drain offset region and the second drain offset region are on opposite sides of the gate electrode.

7. The thin film transistor of claim 6, wherein the first source electrode and the second source electrode are on opposite sides of the gate electrode, and the first drain electrode and the second drain electrode are on opposite sides of the gate electrode.

8. The thin film transistor of claim 7, wherein the source connection is at a same layer as the first source electrode and the second source electrode.

9. The thin film transistor of claim 8, wherein the source connection is insulated from the gate electrode and crosses the gate electrode.

10. The thin film transistor of claim 8, wherein the first drain electrode and the second drain electrode are at a same layer as, and are coupled through, a drain connection.

11. The thin film transistor of claim 10, wherein the drain connection does not overlap the gate electrode.

12. The thin film transistor of claim 10, wherein the first semiconductor layer and the second semiconductor layer comprise a material selected from the group consisting of amorphous silicon, polysilicon, an oxide semiconductor, microcrystalline silicon, and laser crystallized silicon.

13. The thin film transistor of claim 12, wherein a width of the first source offset region is a distance between the gate electrode and the first source electrode and is in a range of about 1 μm to about 10 μm, and a width of the first drain offset region is a distance between the gate electrode and the first drain electrode and is in a range of about 1 μm to about 10 μm, and
wherein a width of the second source offset region is a distance between the gate electrode and the second source electrode and is in a range of about 1 μm to about 10 μm, and a width of the second drain offset region is a distance between the gate electrode and the second drain electrode and is in a range of about 1 μm to about 10 μm.

14. A thin film transistor comprising a plurality of thin film transistors, each of the thin film transistors comprising:
a substrate;
a gate electrode on the substrate;
a gate insulating layer covering the gate electrode;
a first semiconductor layer and a second semiconductor layer overlapping the gate electrode on the gate insulating layer and separated from each other;
a first source electrode and a first drain electrode on the first semiconductor layer and on opposite sides of the gate electrode; and
a second source electrode and a second drain electrode on the second semiconductor layer and on opposite sides of the gate electrode,
wherein the first source electrode of each thin film transistor is coupled to the second source electrode through a source connection overlapping the gate electrode, and the first drain electrode is coupled to the second drain electrode.

15. The thin film transistor of claim 14, wherein the first source electrode and the second source electrode are on opposite sides of the gate electrode, and the first drain electrode and the second drain electrode are on opposite sides of the gate electrode.

16. The thin film transistor of claim 15, wherein the gate electrodes of the plurality of thin film transistors are coupled to each other.

17. The thin film transistor of claim 16, wherein the first source electrodes and the second source electrodes of the plurality of thin film transistors are coupled to each other.

18. The thin film transistor of claim 17, wherein the first drain electrodes and the second drain electrodes of the plurality of thin film transistors are coupled to each other.

19. A thin film transistor comprising:
a substrate;
a first semiconductor layer and a second semiconductor layer on the substrate and separated from each other;
a semiconductor insulating layer covering the first semiconductor layer and the second semiconductor layer;
a gate electrode overlapping the first semiconductor layer and the second semiconductor layer on the semiconductor insulating layer;
a gate insulating layer covering the gate electrode and the semiconductor insulating layer;
a first source electrode and a first drain electrode on the gate insulating layer and on opposite sides of the gate electrode; and
a second source electrode and a second drain electrode on the gate insulating layer and on opposite sides of the gate electrode,
wherein the first source electrode is coupled to the second source electrode through a source connection overlapping the gate electrode, and
the first drain electrode is coupled to the second drain electrode through a drain connection.

20. The thin film transistor of claim 19, wherein the first source electrode and the second source electrode are on opposite sides of the gate electrode, and the first drain electrode and the second drain electrode are on opposite sides of the gate electrode.
